(19) United States
(12) Patent Application Publication
(10) Pub. No.: US 2023/0036587 A1
(43) Pub. Date: Feb. 2, 2023

(54) WAFER ALIGNMENT DEVICE, WAFER ALIGNMENT METHOD AND WAFER ALIGNMENT SYSTEM

(71) Applicant: CHANGXIN MEMORY TECHNOLOGIES, INC., Hefei City (CN)

(72) Inventor: Yiteng WANG, Hefei City (CN)

(21) Appl. No.: 17/456,059

(22) Filed: Nov. 22, 2021

Related U.S. Application Data
(63) Continuation of application No. PCT/CN2021/111763, filed on Aug. 10, 2021.

(30) Foreign Application Priority Data
Jul. 29, 2021 (CN) 202110866097.4

(51) Int. Cl. H01L 21/68; G01B 11/275

(52) U.S. Cl. CPC H01L 21/681; G01B 11/275

(57) ABSTRACT

The present application provides a wafer alignment device, a wafer alignment method and a wafer alignment system. The wafer alignment device includes a detector and an adjustor; the detector is configured to detect an offset of a wafer from a standard position; and the adjustor is configured to adjust a position of the wafer according to the offset of the wafer detected by the detector, so that an error between the position of the wafer and the standard position meets a requirement. The present application can achieve the automatic adjustment of an offset of a wafer, thus achieving the effect of increasing the accuracy of a manipulator subsequently grabbing the wafer.

### CROSS-REFERENCE TO RELATED APPLICATIONS

This application is a continuation application of International Patent Application No. PCT/CN2021/111763, filed on Aug. 10, 2021, which claims priority to Chinese Patent Application No. 202110866097.4, filed with the Chinese Patent Office on Jul. 29, 2021 and entitled “WAFER ALIGNMENT DEVICE, WAFER ALIGNMENT METHOD AND WAFER ALIGNMENT SYSTEM”. International Patent Application No. PCT/CN2021/111763 and Chinese Patent Application No. 202110866097.4 are incorporated herein by reference in their entireties.

### TECHNICAL FIELD

The present application relates to the field of semiconductor manufacturing technologies, in particular, to a wafer alignment device, a wafer alignment method and a wafer alignment system.

### BACKGROUND

A wafer refers to a silicon wafer used in the fabrication of silicon semiconductor integrated circuits, and since it is round, the silicon wafer is called a wafer.

In the field of semiconductor manufacturing technologies, a manipulator is often used to transfer wafers. When a certain process is finished on a wafer and the wafer is required to be transferred to a next process or a temporary storage area, in the process of transferring and fixing the wafer, a relative offset may occur between the wafer and a standard position. If the offset exceeds an error range, the wafer can be easily inclined when fixed. At this point, if the manipulator still continues to grab the wafer according to an originally set procedure, a collision may occur, causing the wafer to be broken or the manipulator and a machine platform to be impacted and deformed.

In an existing related technical solution, only whether the wafer has been put in position is usually detected, but it is impossible to detect whether an offset occurs between the wafer and the standard position or perform adjustment according to the offset of the wafer. Therefore, how to detect whether an offset of a wafer occurs and perform automatic adjustment according to the offset of the wafer is a technical problem to be solved by those skilled in the art.

### SUMMARY

An object of the present application is to provide a wafer alignment device to solve the problem that conventional devices are unable to perform adjustment according to a wafer offset, so as to prevent a collision when a manipulator is grabbing a wafer and decrease a wafer rejection rate and the probability of the manipulator and a machine platform being impacted and deformed. By using a detector to detect an offset of a wafer and an adjustor to automatically adjust a position of the wafer, the effect of increasing the accuracy of the manipulator subsequently grabbing the wafer can be achieved.

In order to solve the aforementioned technical problems, a first aspect of the present application provides a wafer alignment device, including: a detector and an adjustor; the detector being configured to detect an offset of a wafer from a standard position; and the adjustor being configured to adjust a position of the wafer according to the offset of the wafer detected by the detector, so that an error between the position of the wafer and the standard position meets a requirement.

A second aspect of the present application provides a wafer alignment method, including: detecting an offset of a wafer from a standard position; and adjusting a position of the wafer according to the detected offset of the wafer, so that an error between the position of the wafer and the standard position meets a requirement.

A third aspect of the present application provides a wafer alignment system, including: a detection module configured to detect an offset of a wafer from a standard position; and an adjustment module configured to adjust a position of the wafer according to the offset of the wafer detected by the detection module, so that an error between the position of the wafer and the standard position meets a requirement.

### BRIEF DESCRIPTION OF DRAWINGS

In order to more clearly illustrate the technical solutions in embodiments of the present application or a prior art, the accompanying drawings required to be used in the description of the embodiments will be briefly introduced below. Apparently, the accompanying drawings in the following description only show some embodiments of the present application, and those of ordinary skill in the art can still derive other drawings from these accompanying drawings without creative efforts.

FIG. 1 is a schematic structural diagram showing a standard position on a machine platform in a related art;

FIG. 2 is a schematic cutaway structural diagram according to one preferred embodiment of the present application;

FIG. 3 is a schematic side structural diagram according to one preferred embodiment of the present application;

FIG. 4 is a schematic structural diagram showing an adjustor according to one preferred embodiment of the present application;

FIG. 5 is a schematic structural diagram showing a suction surface of a vacuum suction plate according to one preferred embodiment of the present application; and

FIG. 6 is a schematic diagram of an adjustment flow of a wafer alignment device according to one preferred embodiment of the present application.

### REFERENCE NUMERALS

1. machine platform; 2. vacuum suction tube; 21. air source tube; 3. wafer; 41. photoelectric sensor group; 411. photoelectric sensor; 4111. light source generator; 4112. signal receiver; 5. adjustor; 51. fixing and releasing assembly; 511. vacuum suction plate; 5111. suction surface; 51111. air hole; 512. suction tube; 521. horizontal moving mechanism; 5211. slide rail; 52111. screw shaft; 52112. fixed baffle; 5212. slider; 5213. step motor; 522. cylinder unit; 6. fixed iron plate; 7. reflective photoelectric sensor group.

### DESCRIPTION OF EMBODIMENTS

In order to make the object, technical solution and advantages of the present application clearer, the present application will be further described in detail below in conjunction with specific embodiments and with reference to the accompanying drawings. It should be understood that these descriptions are merely exemplary rather than intended to limit the scope of the present application.

### First Embodiment

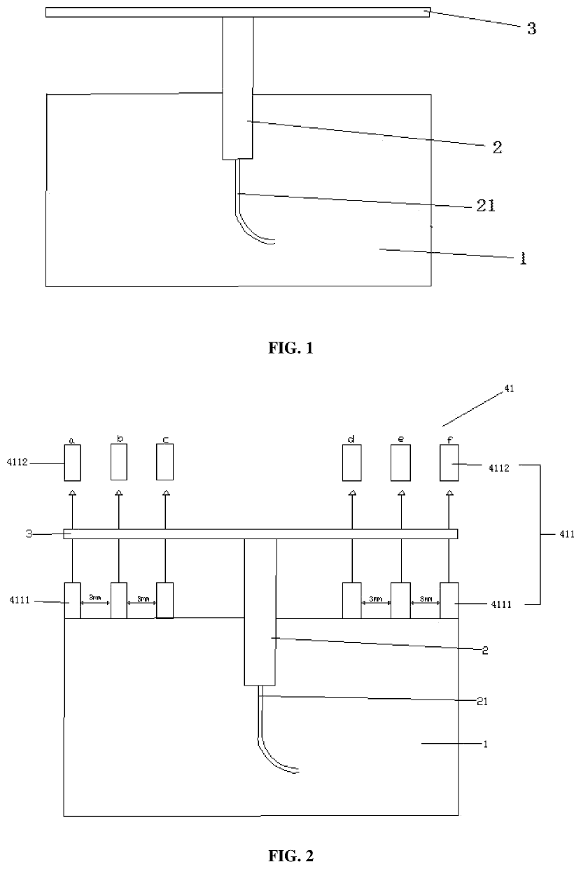

As shown in FIG. 1, the present embodiment provides a wafer alignment device, including a machine platform 1, which is provided with a standard position configured to provide a reference for the correct placement of a wafer 3. In the embodiments of the present application, the form of the standard position is not limited. Only taking a vacuum suction tube 2 as an example for illustration, the vacuum suction tube 2 is vertically fixed on a surface of the machine platform 1, and is connected to an external air source tube 21, which supplies a negative pressure into the vacuum suction tube 2. When the wafer 3 is horizontally placed at an upper end of the vacuum suction tube 2, the negative pressure is supplied into the vacuum suction tube 2 through the air source tube 21, so that the wafer 3 is fixed on the vacuum suction tube 2 by suction.

When a center of the wafer 3 coincides with a central position of the vacuum suction tube 2, at this point, a position of the wafer 3 is not offset relative to the vacuum suction tube 2, and therefore is not required to be adjusted. When an offset of the center of the wafer 3 from the center of the vacuum suction tube 2 exceeds an error range, at this point, the position of the wafer 3 is offset, and therefore is required to be adjusted.

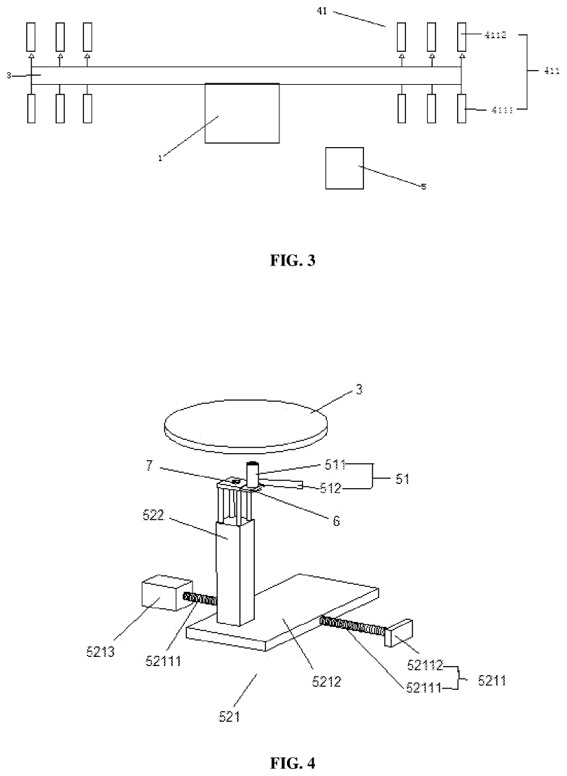

As shown in FIGS. 2 and 3, a detector and an adjustor 5 are also disposed on the machine platform 1. The detector is configured to detect an offset of the wafer 3 from the center of the vacuum suction tube 2. When the offset is excessive, a severe collision may occur when a manipulator is grabbing the wafer 3. Therefore, it is required to control the manipulator to stop the action of grabbing the wafer 3, thus protecting the wafer 3 and the manipulator. The wafer 3 can be automatically adjusted by the adjustor 5 according to the offset of the wafer 3 detected by the detector, so that an error of the wafer 3 offset from the vacuum suction tube 2 can meet a requirement, thus ensuring that the manipulator will not severely collide with the wafer 3 in the process of subsequently grabbing the wafer 3, thus protecting the wafer 3. Consequently, a number of operators is reduced, the difficulty of operation is decreased, and adjustment is automatically performed under the condition that the offset of the wafer 3 occurs on the machine platform 1, increasing a utilization rate of the machine platform 1.

As shown in FIG. 2, in a specific embodiment, the detector includes a plurality of photoelectric sensor groups 41, which are disposed in a circumferential array around the center of the vacuum suction tube 2, and a connecting line between the two photoelectric sensor groups 41 passes through the center of the vacuum suction tube 2 and is arranged centrosymmetrically. Each photoelectric sensor group 41 includes a plurality of photoelectric sensors 411 with different distances from the center of the vacuum suction tube 2. The photoelectric sensors 411 of each photoelectric sensor group 41 are located in a range with the center of the vacuum suction tube 2 as a circle center and a radius of the wafer 3 as a radius.

Further, in each photoelectric sensor group 41, a distance from the photoelectric sensor 411 farthest from the center of the vacuum suction tube 2 to the center of the vacuum suction tube 2 is equal to the radius of the wafer 3, and a connecting line between the photoelectric sensors 411 of each photoelectric sensor group 41 passes through the center of the vacuum suction tube 2.

The photoelectric sensor 411 includes a light source generator 4111 and a signal receiver 4112, which are oppositely disposed at an upper position and a lower position, and the wafer 3 is located between the light source generator 4111 and the signal receiver 4112 when fixed. Signals are transmitted by the light source generator 4111 and received by the signal receiver 4112, so as to judge an offset of the wafer 3. When the offset of the wafer 3 is within the error range, at this point, the wafer 3 just blocks all the signals transmitted by the light source generator 4111, so that the signal receiver 4112 cannot receive the signals, and as a result, the light of the signal receiver 4112 is turned out, which means that the offset of the wafer 3 is within the error range.

In order to facilitate further understanding, a pair of photoelectric sensor groups 41 is taken as an example for illustration, with three photoelectric sensors 411 in each photoelectric sensor group 41 as an example. The signal receivers 4112 in the photoelectric sensors 411 in the present embodiment are sequentially marked as abcdef from the left to the right, with a, b and c as one group located at the position of one end of the wafer 3 and d, e and f as the other group oppositely disposed at the position of the other end of the wafer 3. When the wafer 3 is fixed on the vacuum suction tube 2, the light source generators 4111 and the signal receivers 4112 in each group simultaneously measure a position of the wafer 3. In the present embodiment, according to control over the error range of the wafer 3 being offset from the center of the vacuum suction tube 2, a distance between each two adjacent photoelectric sensors 411 is preferably 3 mm Specific conditions are as follows:

1. under a normal condition, light signals of abcdef are: off/off/off/off/off/off;

2. under an abnormal condition, the light signals are:

off/off/off/off/off/on, among which off denotes that the light of the signal receivers 4112 is turned off and on denotes that the light of the signal receivers 4112 is turned on. This indicates that the signal receiver 4112 (f) does not detect the wafer 3 and the wafer 3 is offset to the left by 0 mm to 3 mm, and because 0 mm to 3 mm are within the acceptable error range, the position of the wafer is not required to be adjusted for the time being.

off/off/off/off/on/on indicates that the signal receivers 4112 (e and f) do not detect the wafer 3 and the wafer 3 is offset to the left by 3 mm to 6 mm, and at this point, because the offset has exceeded the acceptable error range, the position of the wafer is required to be adjusted.

off/off/off/on/on/on indicates that the signal receivers 4112 (d, e and f) do not detect the wafer 3 and the wafer 3 is offset to the left by more than 6 mm, and therefore, the position of the wafer is required to be adjusted as well.

Similarly, when the light signals are: on/off/off/off/off/off, this indicates that the signal receiver 4112 (a) does not detect the wafer 3 and the wafer 3 is offset to the right by 0 mm to 3 mm, and since 0 mm to 3 mm are within the acceptable error range, the position of the wafer is not required to be adjusted for the time being.

When the light signals are: on/on/off/off/off/off, this indicates that the signal receivers 4112 (a and b) do not detect the wafer 3 and the wafer 3 is offset to the right by 3 mm to 6 mm, and therefore, the position of the wafer is required to be adjusted.

When the light signals are: on/on/on/off/off/off, this indicates that the signal receivers 4112 (a, b and c) do not detect the wafer 3 and the wafer 3 is offset to the right by more than 6 mm, and therefore, the position of the wafer is required to be adjusted.

According to the to-be-adjusted offset of the wafer 3 acquired by the detector, adjustment is performed by the adjustor 5.

As shown in FIGS. 3 and 4, in a specific embodiment, the adjustor 5 includes a fixing and releasing assembly 51 and a fine adjustment assembly, with the fixing and releasing assembly 51 configured to fix or release the wafer 3 and the fine adjustment assembly configured to adjust the position of the wafer 3. When the wafer 3 is offset, at this point, the vacuum suction tube 2 does not produce an acting force on the wafer 3, but the fixing and release assembly 51 fixes the wafer 3. The offset of the fixed wafer 3 is corrected under the action of the fine adjustment assembly, and after correction, the fixing and releasing assembly 51 releases the wafer 3, thus completing the adjustment of the wafer 3.

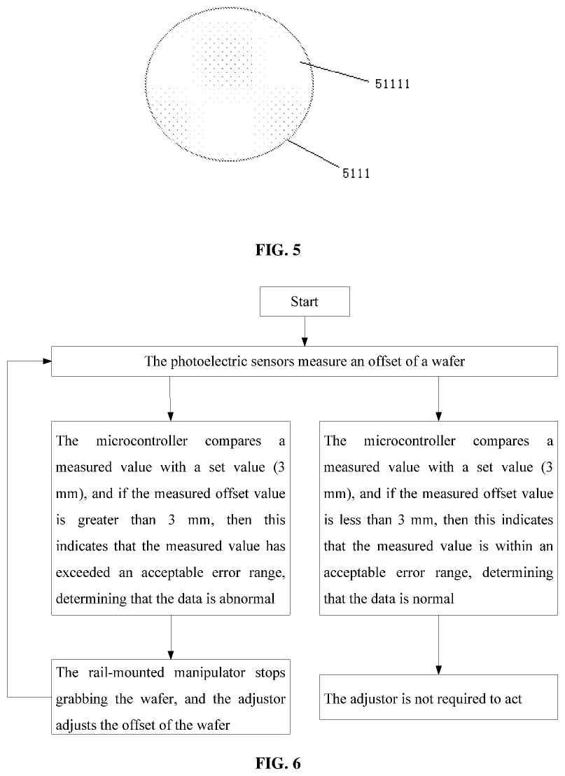

As shown in FIGS. 4 and 5, optionally, the fixing and releasing assembly 51 includes a vacuum suction plate 511 and an air suction tube 512, with the vacuum suction plate 511 arranged as a cylindrical shape with a cavity and the vacuum suction plate 511 disposed vertically and located at a position under the wafer 3. An upper surface of the vacuum suction plate 511 is arranged as a suction surface 5111, which is provided with air holes 51111 arranged evenly, and the air holes 51111 and the cavity of the vacuum suction plate 511 are communicated with each other. One end of the air suction tube 512 is connected to the vacuum suction plate 511 and communicated with the cavity of the vacuum suction plate 511. Optionally, the vacuum suction plate 511 may be provided with a connector, and the air suction tube 512 and the connector may be fixed together by employing screw connection, snap-fit or other methods.

An air source with negative pressure is supplied to the vacuum suction plate 511 through the air suction tube 512, so as to fix the wafer 3 onto the vacuum suction plate 511 by suction. The vacuum suction plate 511 and the vacuum suction tube 2 are used in cooperation with each other. When the wafer 3 is not required to be adjusted, the vacuum suction tube 2 plays the role of fixing the wafer 3 by suction. When the wafer 3 is required to be adjusted, at this point, the vacuum suction tube 2 no longer sucks the wafer 3, but the vacuum suction plate 511 sucks the wafer 3 instead. After the position is adjusted by the fine adjustment assembly, the vacuum suction plate 511 removes the suction fixing effect on the wafer 3.

As shown in FIG. 4, optionally, the fine adjustment assembly includes a horizontal moving mechanism 521 and a vertical lifting mechanism, with the vertical lifting mechanism disposed on the horizontal moving mechanism 521. The horizontal moving mechanism 521 includes a slide rail 5211, a slider 5212 and a driving part. The slider 5212 is slidably disposed on the slide rail 5211, and the slide rail 5211 may be mounted on a device which can circumferentially rotate along a horizontal direction. Thus, the slider 5212 mounted on the slide rail 5211 can be circumferentially changed at a horizontal position, and a horizontal sliding direction of the slider 5212 can then be adjusted.

The slide rail 5211 includes a screw shaft 52111 and a fixed baffle 52112, with the fixed baffle 52112 serving as a rotation supporting part for the screw shaft 52111. One end of the screw shaft 52111 passes through the slider 5212 and is then rotatably connected to the fixed baffle 52112 through a bearing, while the other end of the screw shaft 52111 is fixedly connected to the driving part. The screw shaft 52111 is in threaded connection with the slider 5212. The screw shaft 52111 is driven to rotate on the fixed baffle 52112 by the driving part, so that the slider 5212 is driven on the screw shaft 52111 in a threaded manner to slide.

The driving part includes a step motor 5213, an output shaft of which is fixedly connected to and coaxially arranged with one end of the screw shaft 52111 far away from the fixed baffle 52112. Power is supplied for the action of the screw shaft 52111 by the step motor 5213.

The vertical lifting mechanism includes a cylinder unit 522, which is vertically disposed. The cylinder unit 522 is located on the slider 5212 and a cylinder body of the cylinder unit 522 is fixedly mounted on the slider 5212. A piston rod of the cylinder unit 522 is fixedly connected to a fixed iron plate 6, and the vacuum suction plate 511 is mounted through the fixed iron plate 6, with a lower end of the vacuum suction plate 511 fixedly mounted on the fixed iron plate 6. When the cylinder unit 522 is required to adjust the wafer 3, the piston rod of the cylinder unit 522 extends and drives the vacuum suction plate 511 to move to under the wafer 3. The vacuum suction plate 511 sucks the wafer 3 under the action of the negative pressure supplied by the air suction tube 512, and then moves along with the slider 5212 according to a measured offset to correct the offset of the wafer 3. After adjustment is complete, the vacuum suction plate 511 on the cylinder unit 522 is released, and the cylinder unit 522 carries the vacuum suction plate 511 to move down to an initial position.

As shown in FIG. 4, optionally, a reflective photoelectric sensor group 7 is also mounted on the fixed iron plate 6. When the cylinder unit 522 is carrying the vacuum suction plate 511 to ascend toward the position of the wafer 3, under a guiding function of the reflective photoelectric sensor group 7, it can be more accurately ensured that the vacuum suction plate 511 can move to under the wafer 3 without collision.

### Second Embodiment

As shown in FIGS. 4 and 6, the present embodiment provides a wafer alignment method, including the following steps:

(Step 1) detecting an offset of the wafer 3 from the standard position;

The six groups of light source generators 4111 and signal receivers 4112 monitor the offset of the wafer 3 on the vacuum suction tube 2. A monitored signal is input into a signal conditioning circuit for filtering and amplification, and is then transmitted to a controller for processing. The controller compares a measured value with a set value. If the data is normal, then the method ends; and if the data is abnormal, then enters Step 2.

(Step 2) adjusting a position of the wafer 3 according to the detected offset of the wafer 3, so that an error between the position of the wafer 3 and the standard position meets a requirement.

The adjusting a position of the wafer 3 according to the detected offset of the wafer 3, so that an error between the position of the wafer 3 and the standard position meets a requirement includes:

the controller comparing the measured value with the set value; if the set value is 3 mm, when it is discovered from the comparison between the measured value and the set value that the offset is greater than 3 mm, determining that the data is abnormal, and the controller communicating with the rail-mounted manipulator and immediately terminating the process of the rail-mounted manipulator grabbing the wafer 3; meanwhile, starting the cylinder unit 522, the piston rod of the cylinder unit 522 carrying the vacuum suction plate 511 to move to a position under the wafer 3 under the guide of the reflective photoelectric sensor group 7, and at this point, the air suction tube 512 supplying a negative pressure to the vacuum suction plate 511, so that the vacuum suction plate 511 firmly fixes the wafer 3 by suction;

the controller transmitting the position information of the offset of the wafer 3 to the step motor 5213, the step motor 5213 controlling the motion of the slider 5212 according to the offset, so that the slider 5212 moves under the drive of the screw shaft 52111, the slider 5212 carrying the vacuum suction plate 5231 with the cylinder unit 522 to perform corresponding adjustment on the wafer 3, and after the distance is measured again and it is confirmed that the position information is correct, ordering the rail-mounted manipulator to resume the process of grabbing the wafer 3.

### Third Embodiment

The present embodiment provides a wafer alignment system, including:

a detection module configured to detect an offset of a wafer from a standard position, the detection module including photoelectric sensors in an example; and

an adjustment module configured to adjust a position of the wafer according to the offset of the wafer detected by the detection module, so that an error between the position of the wafer and the standard position meets a requirement.

The wafer alignment system further includes:

a control module configured to control the adjustment module to adjust the offset of the wafer according to the offset of the wafer from the standard position detected by the detection module, the control module including a microcontroller in an example; and

a manipulator control module in communication connection with the control module, configured to control a rail-mounted manipulator to grab the wafer after the error between the position of the wafer and the standard position meets the requirement.

It may specifically include:

when the wafer is inclined, the photoelectric sensors detecting an offset signal of the wafer and inputting the signal into a signal conditioning circuit for filtering and amplification, then transmitting the signal to the microcontroller for processing, the microcontroller communicating with the manipulator control module, and after receiving a signal of the microcontroller, the manipulator control module immediately terminating the process of the rail-mounted manipulator grabbing the wafer;

the microcontroller transmitting the position information of the offset to the step motor, the step motor carrying the adjustor to perform corresponding adjustment, and after the distance is measured again and the offset of the wafer is adjusted to meet an error range, the manipulator control module ordering the rail-mounted manipulator to resume the process of grabbing the wafer.

It should be understood that the aforementioned specific embodiments of the present application are merely intended to illustrate or explain the principle of the present application rather than constitute a limitation to the present application. Therefore, any modification, equivalent substitution, improvement and the like made without departing from the spirit and scope of the present application shall be included in the protection scope of the present application. In addition, the appended claims of the present application are intended to cover all changes and modifications that fall within the scope and boundaries of the appended claims or equivalents of such scope and boundaries.

What is claimed is:

1. A wafer alignment device, comprising a detector and an adjustor;
the detector being configured to detect an offset of a wafer from a standard position; and
the adjustor being configured to adjust a position of the wafer according to the offset of the wafer detected by the detector, so that an error between the position of the wafer and the standard position meets a requirement.

2. The wafer alignment device of claim 1, wherein the detector comprises a plurality of photoelectric sensor groups, each of which comprises a plurality of photoelectric sensors, and distances between the plurality of photoelectric sensors and a center of the standard position are different;
the plurality of photoelectric sensors in each photoelectric sensor group are all located within a range with the center of the standard position as a circle center and a radius of the wafer as a radius; and
in each photoelectric sensor group, a distance between the photoelectric sensor farthest from the center of the standard position and the center of the standard position is equal to the radius of the wafer.

3. The wafer alignment device of claim 2, wherein the plurality of the photoelectric sensor groups are disposed in a circumferential array around the center of the standard position, and a connecting line between the photoelectric sensors of each photoelectric sensor group passes through the center of the standard position; and a connecting line between the two of the photoelectric sensor groups passes through the center of the standard position and is arranged centrosymmetrically.

4. The wafer alignment device of claim 2, wherein the photoelectric sensor comprises a light source generator and a signal receiver, which are oppositely disposed at an upper position and a lower position, and the wafer is located between the light source generator and the signal receiver when fixed.

5. The wafer alignment device of claim 3, wherein the photoelectric sensor comprises a light source generator and a signal receiver, which are oppositely disposed at an upper position and a lower position, and the wafer is located between the light source generator and the signal receiver when fixed.

6. The wafer alignment device of claim 1, wherein the adjustor comprises a fixing and releasing assembly configured to fix or release the wafer and a fine adjustment assembly configured to perform adjustment according to the offset of the wafer when the wafer is fixed by the fixing and releasing assembly.

7. The wafer alignment device of claim 6, wherein the fixing and releasing assembly comprises a vacuum suction plate, which is provided with a suction surface, and the suction surface can suck a surface of the wafer under the action of an external vacuum source.

8. The wafer alignment device of claim 7, wherein the fine adjustment assembly comprises a horizontal moving mechanism horizontally moving in a horizontal direction, a vertical lifting mechanism is disposed on the horizontal moving mechanism, and the vacuum suction plate is disposed on the vertical lifting mechanism.

9. The wafer alignment device of claim 8, wherein the horizontal moving mechanism comprises a slide rail, a slider sliding on the slide rail and a driving part driving the slider to slide on the slide rail, and the vertical lifting mechanism is disposed on the slider.

10. A wafer alignment method, comprising:
detecting an offset of a wafer from a standard position; and
adjusting a position of the wafer according to the detected offset of the wafer, so that an error between the position of the wafer and the standard position meets a requirement.

11. The wafer alignment method of claim 10, wherein the step of adjusting a position of the wafer according to the detected offset of the wafer, so that an error between the position of the wafer and the standard position meets a requirement specifically comprises:
a vertical lifting mechanism driving a vacuum suction plate to move up, until a suction surface of the vacuum suction plate sucks a surface of the wafer; and
a driving part driving a slider to slide on a slide rail, and the slider driving the vertical lifting mechanism and the wafer to move horizontally while sliding, so that the position of the wafer is adjusted.

12. A wafer alignment system, comprising:
a detection module configured to detect an offset of a wafer from a standard position; and
an adjustment module configured to adjust a position of the wafer according to the offset of the wafer detected by the detection module, so that an error between the position of the wafer and the standard position meets a requirement.

13. The wafer alignment system of claim 12, further comprising:
a control module configured to control the adjustment module to adjust the offset of the wafer according to the offset of the wafer from the standard position detected by the detection module; and
a manipulator control module in communication connection with the control module, configured to control a rail-mounted manipulator to grab the wafer after the error between the position of the wafer and the standard position meets the requirement.

14. The wafer alignment system of claim 12, wherein the detection module comprises photoelectric sensors.
